(19) United States
(12) Patent Application Publication
(10) Pub. No.: US 2016/0086758 A1
(43) Pub. Date: Mar. 24, 2016

(54) LIQUID DROPLET INJECTING APPARATUS AND ION SOURCE

(71) Applicant: CANON KABUSHIKI KAISHA, Ohta-ku, Tokyo (JP)

(72) Inventor: Kota Iwasaki, Atsugi-shi (JP)

(21) Appl. No.: 14/888,078

(22) PCT Filed: Apr. 18, 2014
(86) PCT No.: PCT/JP2014/062033

§ 371 Date: Oct. 29, 2015

(30) Foreign Application Priority Data
Apr. 30, 2013 (JP) 2013-096003

(51) Int. Cl. H01J 27/02; H01J 37/18; H01J 49/26; B05B 17/06; B05B 15/02; H01J 49/14; H01J 27/20

(52) U.S. Cl. CPC H01J 27/026; H01J 49/147; H01J 37/18; H01J 27/205; B05B 17/06; B05B 15/02; H01J 49/26; H01J 2237/182; H01J 2237/0812

(57) ABSTRACT

In the known liquid droplet injecting apparatus, when a tube and a nozzle are heated in order to prevent deposition of a solid source material of liquid droplets, the efficiency of injection of liquid droplets into a vacuum vessel is decreased by evaporation of the liquid droplets. The present invention provides a liquid droplet injecting apparatus capable of efficiently injecting liquid droplets into a vacuum vessel. The liquid droplet injecting apparatus includes a liquid container which holds a liquid and whose inside pressure can be adjusted, a liquid droplet generating unit configured to generate liquid droplets from the liquid held in the liquid container, a nozzle which injects the liquid droplets generated in the liquid container, a connecting tube which connects the nozzle and the liquid container, and a first heating unit configured to heat at least one of the connecting tube and the nozzle.

### TECHNICAL FIELD

The present invention relates to an apparatus that produces a molecular or cluster ion beam by injecting liquid droplets into a vacuum.

### BACKGROUND ART

By injecting a carrier gas containing liquid droplets through a nozzle into a vacuum vessel, clusters can be introduced into a vacuum. Clusters vary in size, from a cluster consisting of several molecules to a large cluster consisting of 10,000 or more molecules. Clusters are composed of molecules of a liquid constituting droplets or other gas molecules. When clusters are ionized by electron bombardment or photoionization, cluster ions are generated.

Irradiation of a solid surface with cluster ions is used in a surface treatment process, such as etching, sputtering, or film deposition. Furthermore, when polyatomic molecules are irradiated with cluster ions, the polyatomic molecules can be ionized without being fragmented, and this technique is also effective for application to surface analyzing devices.

Examples of a method of forming liquid droplets include (1) a method in which an ultrasonic vibrator is installed in a container in which a liquid for forming droplets (liquid source material) is placed, and by applying ultrasonic vibration to the liquid, liquid droplets in the form of a mist are generated from the surface of the liquid; (2) a method in which a gas is injected below the surface of a liquid to generate bubbles in the liquid, and liquid droplets are generated when the bubbles burst open at the surface of the liquid; and (3) a method in which a liquid source material is heated, evaporated, and then condensed to generate liquid droplets.

As the method for extracting liquid droplets from a container, which were previously generated in the container, a method is used in which a gas is introduced through a tube connected to the container, and the gas and liquid droplets contained in the gas stream are led out of the container.

The tube is connected to a nozzle disposed in a vacuum vessel. The gas and liquid droplets are injected through the nozzle into a vacuum (PTL 1). From the nozzle to the inside of the vacuum vessel, the pressure rapidly decreases, and therefore, the gas is cooled by adiabatic expansion. On the other hand, the liquid droplets solidify when brought into contact with the inner walls of the nozzle and the tube, and the liquid droplets are transformed into a solid (solid source material) which is deposited.

### CITATION LIST

### Patent Literature

PTL 1 Japanese Patent Laid-Open No. 2003-329556

### SUMMARY OF INVENTION

### Technical Problem

When the solid source material is deposited on the inner walls of the nozzle and the tube, the flow channel of the gas containing the liquid droplets is narrowed, and the amount of liquid droplets injected decreases. In some cases, the flow channel may be blocked. In order to solve this problem, the tube and the nozzle may be heated so that the liquid droplets can be prevented from solidifying on the inner walls of the nozzle and the tube.

However, when the temperature of the tube and the nozzle is increased, the temperature of the gas and the liquid droplets is also increased by heat transfer from the inner walls thereof. In the gaseous source material whose temperature is increased, the vapor pressure is also increased, and evaporation of the liquid droplets is promoted. As a result, before the liquid droplets reach the inside of the vacuum vessel, the number and size of the liquid droplets decrease in the tube and the nozzle, which is a problem.

As described above, in the known liquid droplet injecting apparatus, when the tube and the nozzle are heated in order to prevent deposition of the solid source material, which causes a decrease in the amount of liquid droplets injected, the efficiency of injection of liquid droplets into the vacuum vessel is decreased by evaporation of the liquid droplets, which is a problem.

The present invention provides a liquid droplet injecting apparatus capable of efficiently injecting liquid droplets into a vacuum vessel.

According to aspects of the present invention, a liquid droplet injecting apparatus includes a liquid container which holds a liquid and whose inside pressure can be adjusted, a liquid droplet generating unit configured to generate liquid droplets from the liquid held in the liquid container, a nozzle which injects the liquid droplets generated in the liquid container, a connecting tube which connects the nozzle and the liquid container, and a first heating unit configured to heat at least one of the tube and the nozzle.

According to aspects of the present invention, it is possible to provide a liquid droplet injecting apparatus capable of efficiently injecting liquid droplets into a vacuum vessel.

Further features of the present invention will become apparent from the following description of exemplary embodiments with reference to the attached drawings.

### BRIEF DESCRIPTION OF DRAWINGS

FIG. 1A is a schematic view showing a cluster ion irradiation apparatus provided with a liquid droplet injecting apparatus according to a first embodiment.

FIG. 1B is a schematic view showing a cluster ion irradiation apparatus provided with a liquid droplet injecting apparatus according to a second embodiment.

FIG. 1C is a graph showing the relationship between the vapor pressure and the temperature of water as an example.

FIG. 2A is a schematic view showing an example of a liquid droplet injecting apparatus according to an embodiment of the present invention.

FIG. 2B is a schematic view showing a liquid droplet injecting apparatus in which bubbles are generated in a liquid source material.

FIG. 2C is a schematic view showing a liquid droplet injecting apparatus in which a heater is provided on a liquid container.

FIG. 2D is a schematic view showing a liquid droplet injecting apparatus which includes a pulse valve.

FIG. 2E is a schematic view showing a liquid droplet injecting apparatus which includes an external heating unit.

FIG. 2F is a schematic view showing a liquid droplet injecting apparatus in which a heater is provided on a connecting tube.

FIG. 3 is a schematic view showing a liquid droplet injecting apparatus which includes a temperature controller.

FIG. 4A is a graph showing the changes in pressure during liquid droplet injection by a liquid droplet injecting apparatus which includes a pulse valve.

FIG. 4B is a graph showing pressure during liquid droplet injection in a continuous injection process.

FIG. 5A is a schematic view showing a liquid droplet injecting apparatus according to a sixth embodiment.

FIG. 5B is a schematic view showing a liquid droplet injecting apparatus according to a seventh embodiment.

FIG. 5C is a schematic view showing a liquid droplet injecting apparatus according to an eighth embodiment.

FIG. 5D is a schematic view showing a modification example of the liquid droplet injecting apparatus according to the eighth embodiment.

### DESCRIPTION OF EMBODIMENTS

### First Embodiment

Description will be made on a method of injecting liquid droplets into a vacuum vessel using a liquid droplet injecting apparatus according to a first embodiment, and a cluster ion irradiation method using a cluster ion irradiation apparatus including the liquid droplet injecting apparatus.

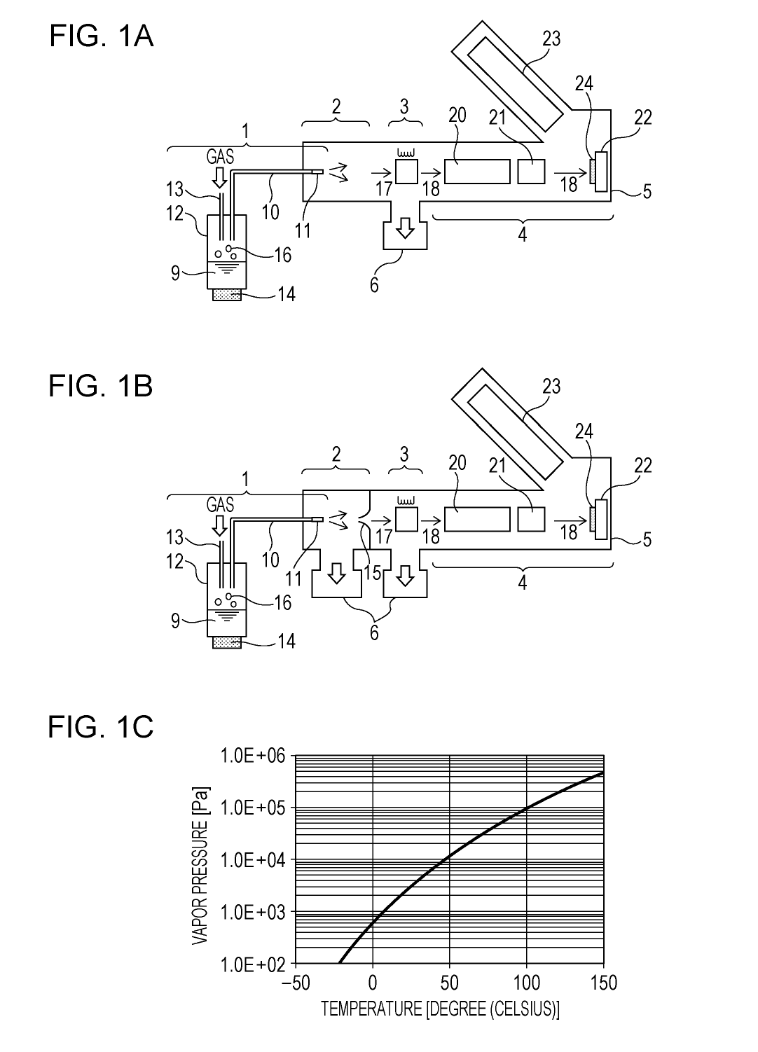

A cluster ion irradiation apparatus includes a liquid droplet injecting apparatus 1, a cluster generation part 2, an ionization part 3, and an irradiation part 4. The latter three parts constitute a vacuum vessel 5, which is exhausted by a vacuum pump 6 (FIG. 1A). The apparatus also includes a signal processing system (not shown).

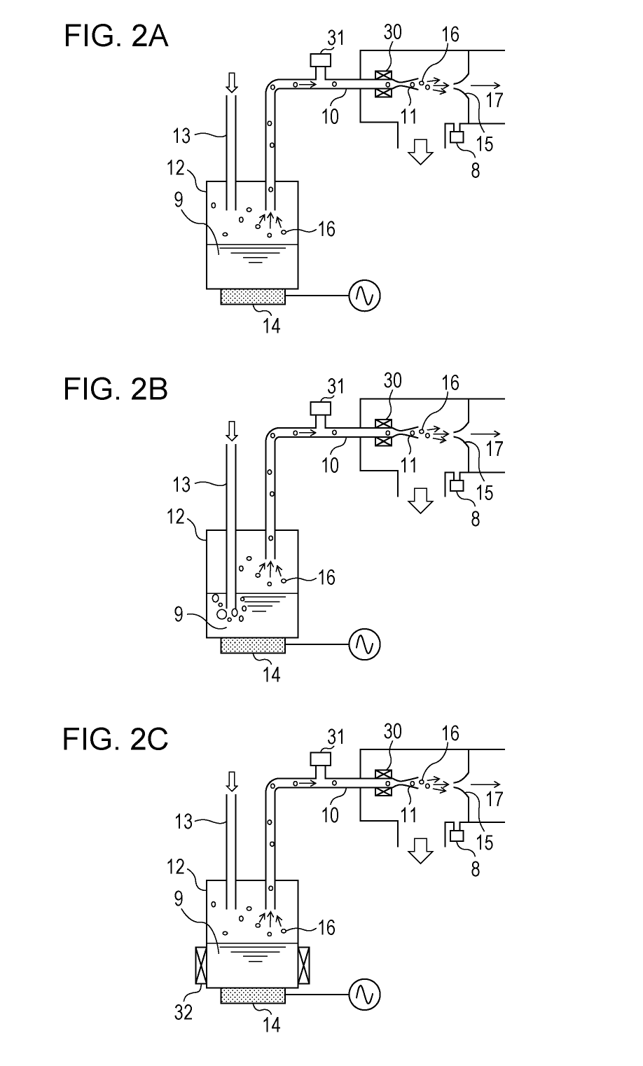

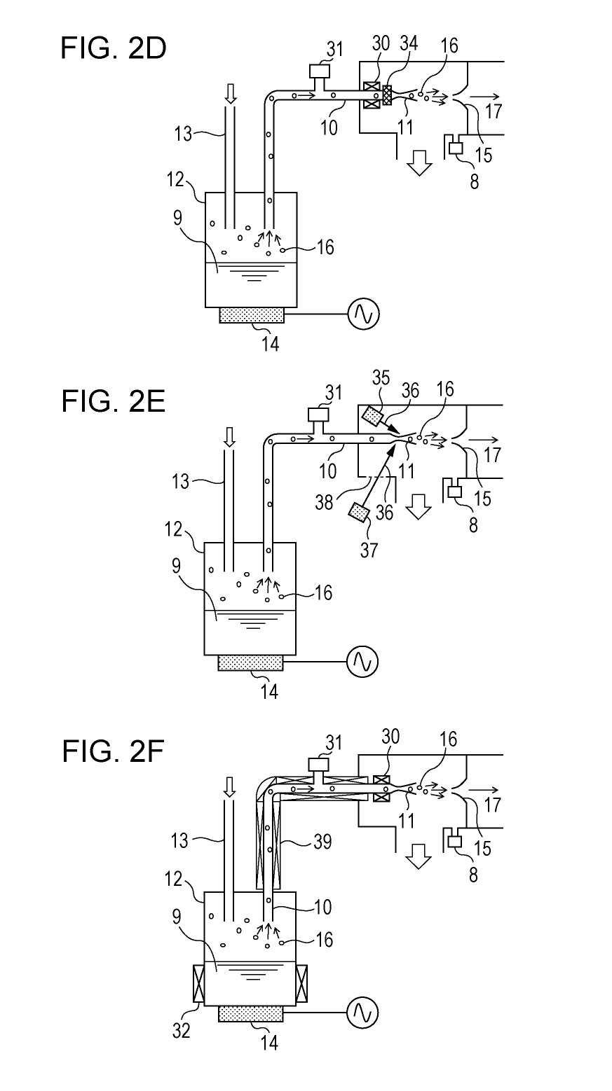

As shown in FIG. 2A, the liquid droplet injecting apparatus 1 includes a liquid container 12 which stores a liquid source material 9 for liquid droplets, a gas introduction tube 13 which introduces a gas into the liquid container, a vibrator 14 which vibrates the liquid source material, a nozzle 11 located in the cluster generation part 2, and a connecting tube 10 which connects the liquid container 12 and the nozzle 11.

The liquid source material 9 may be water or an alcohol, such as ethanol, methanol, or isopropyl alcohol, or may be an organic solvent, such as benzene, acetone, ether, or butyl acetate. The liquid source material may be a mixture of these materials or a non-mixture. Furthermore, an acid, such as acetic acid, formic acid, or trifluoroacetic acid, or a base, such as ammonia, may be mixed into these materials. Furthermore, ammonium acetate or ammonium formate may be mixed thereinto.

When an AC voltage with an appropriate frequency is applied to the vibrator 14, which is a liquid droplet generating unit, the vibrator 14 generates vibration. The frequency is preferably several kilohertz to several hundred megahertz, and more preferably about 100 kHz to 10 MHz.

Since the vibrator 14 vibrates the liquid source material 9 through the liquid container 12, liquid droplets 16 are generated from the surface of the liquid source material 9 by means of vibration energy.

On the other hand, from the gas introduction tube 13, a gas that is the same as the vaporized liquid source material 9, such as water vapor, a gas-phase alcohol, or a vaporized organic solvent, may be introduced. Furthermore, a different gas from the source material gas may be introduced. For example, a noble gas, such as Ar, Ne, He, Kr, or Xe, or a molecular gas, such as H₂, CO₂, Co, N₂, O₂ NO₂, SF₆, Cl₂, or NH₄, may be supplied.

Furthermore, as another liquid droplet generating unit, an end of the gas introduction tube 13 may be disposed below the surface of the liquid source material 9 (FIG. 2B). By introducing a gas from the gas introduction tube 13, bubbles may be generated in the liquid source material, and liquid droplets 16 may be generated from the liquid source material. The same gas as that of the liquid source material 9 may be introduced, or a gas different from the source material gas may be introduced as in the case described above.

The gas that fills the liquid container 12 is guided through the connecting tube 10 to the nozzle 11, and injected into the vacuum vessel. At that time, as shown in FIG. 2A, the liquid droplets 16 in the liquid container 12 move along the gas flow and are injected into the vacuum vessel. During that period, since the temperature of the gas is decreased by adiabatic expansion, the temperature of the liquid droplets 16 is decreased.

Regarding the shape of the nozzle, a Laval nozzle, such as the nozzle 11 shown in FIGS. 2A to 2F, or a conical nozzle having a conical opening may be used. Alternatively, an aperture-type nozzle having an opening with a constant size may be used.

When the cooled liquid droplets 16 are brought into contact with the inner wall of the nozzle 11, they solidify on the inner wall and are deposited as a solid source material. As the amount of the solid source material deposited increases, the flow channel of the nozzle may become blocked, which makes it difficult to supply liquid droplets.

Accordingly, in this embodiment, a heater 30 heats the nozzle 11 to suppress deposition of the solid source material. On the other hand, when the nozzle 11 is heated, the temperature of the gas and liquid droplets 16 passing through the connecting tube 10 is also increased by radiation from the inner wall of the nozzle 11 and thermal conduction. As a result, before the liquid droplets reach the inside of the vacuum vessel, evaporation of the source material gas from the liquid droplets 16 is promoted.

Description will be made below, taking the case where the source material gas is water as an example. The vapor pressure of water (refer to FIG. 1C) is 0.6 kPa at 0 degree (Celsius) at which ice starts to form. When the nozzle is heated, for example, to 50 degrees (Celsius) in order to prevent deposition of ice, which is the solid source material, on the inner wall of the nozzle, the vapor pressure of water increases to 12.3 kPa.

The evaporation of the gas from a liquid droplet (water droplet in this case) is determined by the temperature and the vapor pressure as shown in expression 1 below.

$$[ Math . 1 ] \\ {Γ}_{out} = - \frac{P}{\sqrt{2 π mkT}} \qquad ( 1 )$$

where Γₒᵤₜ is the gas evaporation per unit area from a droplet, P is the vapor pressure, m is the mass of a gas molecule, k is the Boltzmann constant, and T is the temperature. The unit of measure for temperature is Kelvin.

When comparison is made between a droplet having a temperature T1 and a droplet having a temperature T2, the ratio of the water evaporation per unit area Γₒᵤₜ₁ at T1 to the water evaporation per unit area Γₒᵤₜ₂ at T2 is given by expression 2 below.

$$[ Math . 2 ] \\ \frac{{Γ}_{out 1}}{{Γ}_{out 2}} = - \frac{{P}_{1}}{{P}_{2}} \sqrt{\frac{{T}_{2}}{{T}_{1}}} \qquad ( 2 )$$

where P1 and P2 are vapor pressures at T1 and T2, respectively.

For example, when evaporations are specifically compared under the assumption that T1 is 50 degrees (Celsius) (323 K) and T2 is 0 degree (Celsius) (273 K), the water evaporation at 50 degrees (Celsius) is 18.8 times larger than that at 0 degree (Celsius). Therefore, water is rapidly evaporated from the liquid droplet.

On the other hand, when water vapor with 12.3 kPa or more is introduced into the connecting tube 10 in advance, the partial pressure Pᵢₙ of the substance constituting droplets (liquid source material) in the connecting tube 10 is higher than the vapor pressure of the substance. The amount of water vapor incident on a liquid droplet surface Γᵢₙ is given by expression 3 below.

$$[ Math . 3 ] \\ {Γ}_{in} = \frac{{P}_{in}}{\sqrt{2 π {mkT}_{g}}} \qquad ( 3 )$$

Thus, when the relationship of expression 4 is satisfied, the water evaporation Γₒᵤₜ and the amount of water incident on the liquid droplet surface Γᵢₙ are in balance, or the latter is larger than the former. Therefore, evaporation of the liquid droplet is suppressed. Here, T_{g} is the temperature of water vapor.

[Math. 4]

Γₒᵤₜ+Γᵢₙ≧0 (4)

Consequently, while suppressing deposition of ice, which is the solid source material, on the inner wall of the nozzle, it is possible to suppress the liquid droplets 16 from evaporating before being injected into the vacuum vessel, thus decreasing the number and size of the liquid droplets 16. Note that the conditions described above apply even to a non-equilibrium state in which the liquid droplet and water vapor have different temperatures. The temperatures of the inner wall of the nozzle, water vapor, and the liquid droplets may not be the same.

As the method for introducing water vapor into the connecting tube 10, as shown in FIG. 2C, by adjusting the temperature of the liquid source material 9 stored in the liquid container 12 to a specific temperature (50 degrees (Celsius) in the example described above) using a liquid container heater 32, water vapor may be generated in the liquid container 12. Alternatively, as shown in FIG. 2A, water vapor may be introduced from the outside of the liquid container 12 through the gas introduction tube 13.

In particular, in the former case, since the liquid source material 9 and the liquid which controls the vapor pressure are the same, the change in temperature of the liquid droplets 16 from the liquid container 12 to the nozzle 11 is small, and thus an effect is obtained in which the change in size or number of the liquid droplets 16 can be decreased.

The temperature for heating the nozzle 11 is not limited to 50 degrees (Celsius), and may be a temperature higher than the freezing point of the liquid source material. Furthermore, the temperature may be higher than room temperature and, for example, may be 100 degrees (Celsius) or higher.

A pressure measuring unit 31 configured to measure the internal pressure is provided in the connecting tube 10 extending from the liquid container 12 to the nozzle 11. The pressure measuring unit 31 may be a total pressure gauge or a partial pressure gauge.

The total pressure gauge may be a diaphragm gauge, a Bourdon tube, or a Pirani vacuum gauge, and is capable of measuring high pressures. Since high vapor pressures can be measured using a total pressure gauge, a source material gas having a high pressure can be introduced, and thus the temperature of the nozzle 11 can be further increased.

On the other hand, in the case where a partial pressure gauge is used as the pressure measuring unit 31, the partial pressure of the source material gas can be measured even when the source material gas and another gas exist in the connecting tube 10. Therefore, an effect is obtained in which the pressure of the source material gas can be controlled with more accuracy by the method described later. Note that the partial pressure gauge may be a semiconductor sensor, a quadrupole-type partial pressure gauge, or a magnetic-sector-type partial pressure gauge.

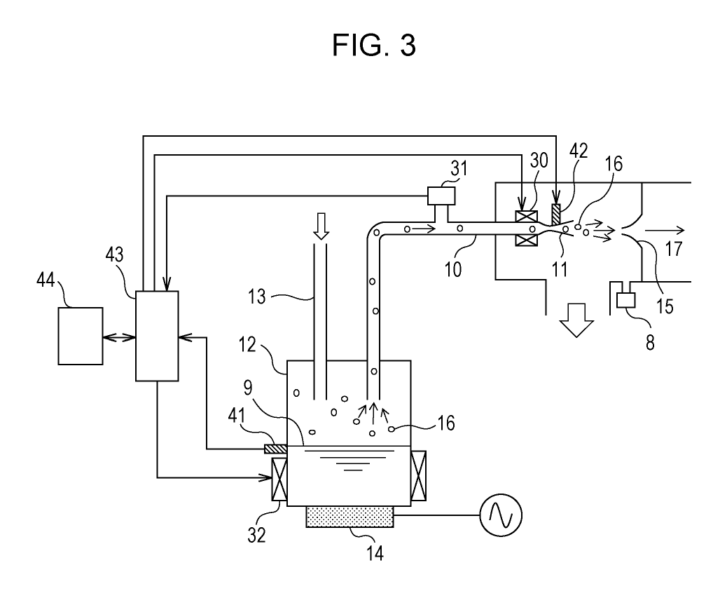

The temperature of the liquid container 12 may be adjusted, as shown in FIG. 3, by controlling the amount of heat generation of the liquid container heater 32 such that the liquid container 12 has a desired temperature on the basis of the measured value of the pressure which a temperature controller 43 has received from the pressure measuring unit 31 (pressure measurement value). For example, a method may be employed in which the temperature controller 43 reads a predetermined reference value of pressure (pressure reference value) stored in a memory unit 44; when the pressure measurement value is lower than the pressure reference value, the amount of heat generation of the liquid container heater 32 is increased so that the temperature of the liquid container 12 can be increased; and when the pressure measurement value is higher than the pressure reference value, the amount of heat generation of the liquid container heater 32 is decreased so that the temperature of the liquid container 12 can be decreased. At that time, the temperature of the liquid container 12 (liquid container temperature) may be measured by a thermometer 41, and the measured temperature may be sent from the thermometer 41 to the temperature controller 43. The temperature controller 43 may control the amount of heat generation of the liquid container heater 32 on the basis of the measured temperature.

On the other hand, the temperature of the nozzle 11 may be controlled by the temperature controller 43. Similarly to the above, the temperature controller 43 may receive the temperature of the nozzle 11 (nozzle temperature) from a nozzle thermometer 42 and control the amount of heat generation of a nozzle heater 30.

Furthermore, control may be performed such that, when the difference between the pressure measurement value and the pressure reference value is within a given pressure difference (allowable pressure difference), or when the former value is higher than the latter value, the temperature of the liquid container 12 at the time of measurement of the pressure by the pressure measuring unit 31 is maintained. The case where the pressure value is used has been described above. The partial pressure value may be used.

Liquid droplets may be generated by another method in which the liquid container 12 is heated by the liquid container heater 32 to evaporate the source material gas, and then the evaporated source material gas is condensed to generate liquid droplets. In this case, a liquid droplet introduction apparatus which is not provided with a vibrator 14 may be used.

A cluster beam 17 is generated from at least some of the liquid droplets 16 injected together with the gas from the nozzle 11 into the cluster generation part 2.

The generated cluster beam 17 enters the ionization part 3 as shown in FIG. 1A. Furthermore, the liquid droplets 16 may enter the ionization part 3. An electron source, such as a hot filament, is disposed in the ionization part 3. Electrons generated by the electron source collide with at least one of the cluster beam 17 and the liquid droplets 16, and thereby some of atoms or molecules constituting the clusters or the liquid droplets 16 are ionized by electron bombardment to produce a cluster ion beam 18. The cluster generation part 2 and the ionization part 3 constitute an ion source.

Besides using electron bombardment, ionization may be performed using an electromagnetic wave, such as laser, excited atoms/molecules, or ionizing radiation.

Subsequently, the cluster ion beam enters the irradiation part 4. The irradiation part 4 includes a mass selector 20, a convergent lens 21, and an irradiation stage 22. An analyzer 23 may also be provided therein.

Cluster ions having appropriate size are selected by the mass selector 20, and the selected cluster ions are accelerated or decelerated and focused, as necessary, and then are caused to be incident on an object to be irradiated 24 held on the irradiation stage 22. Note that cluster ions without being size selected may be incident on the object to be irradiated 24.

The object to be irradiated 24 is subjected to sputtering or etching by cluster ions. Furthermore, by analyzing secondary ions or neutral particles generated from the object to be irradiated 24 using the analyzer 23, the apparatus can serve as a surface analyzing device.

When a mass spectrometer is used as the analyzer 23, it is possible to perform secondary ion mass spectrometry by cluster ions. When a neutral particle detector equipped with an ionization device is used as the analyzer 23, it is possible to perform neutral particle mass spectrometry by cluster ions.

### Second Embodiment

A liquid droplet injecting apparatus according to a second embodiment and a cluster ion irradiation apparatus including the liquid droplet injecting apparatus are shown in FIG. 1B.

The liquid droplet injecting apparatus and the cluster ion irradiation apparatus are the same as those in the first embodiment except that the cluster ion generation part 2 and the ionization part 3 are separated by a skimmer 15.

In this embodiment, the liquid droplets 16 injected from the nozzle 11 together with the gas into the cluster generation part pass through the skimmer 15 provided downstream to produce a cluster beam 17.

The cluster beam 17 enters the ionization part 3, and some of atoms or molecules constituting the clusters are ionized by electron bombardment to produce a cluster ion beam 18 as in the first embodiment.

In the case where the skimmer 15 is provided as in this embodiment, even if the introduction amount of the gas or liquid droplets is increased, a rise in the pressure in the ionization part 3 can be reduced, and thus an effect is obtained in which the operation of the ionization part 3 is prevented from being unstabilized by discharge or the like. Furthermore, by decreasing the pressure in the ionization part 3 and the irradiation part 4, the mean free path of the residual gas increases, and the collision frequency between the cluster ion beam and the residual gas decreases. As a result, an effect is obtained in which attenuation of the cluster ion beam can be suppressed.

The pressure P_{b} in the vacuum vessel may be maintained by controlling the gas flow rate such that the mean free path of the residual gas in the ionization part 3 or the irradiation part 4 is a predetermined value or more. The predetermined value may be the geometric size of the vacuum vessel, for example, the distance between the ionization part 3 and the skimmer 15, or the internal diameter or length of the vacuum vessel which stores the ionization part 3 and the like.

Note that, as the mean free path, the value of nitrogen gas calculated from expression 5 below may be used. The unit of measure for λ is [mm], and the unit of measure for P_{b} is [Pa].

[Math. 5]

λ=6.6/P_{b} (5)

### Third Embodiment

A liquid droplet injecting apparatus according to a third embodiment is shown in FIG. 2D. This apparatus is the same as the liquid droplet injecting apparatus according to the first or second embodiment except that a pulse valve 34 that can switch between injection and shutoff of the gas is provided between the nozzle 12 and the connecting tube 10. A cluster ion irradiation apparatus including this liquid droplet injection apparatus is the same as that in the first or second embodiment. Furthermore, the pulse valve 34 may be provided on the connecting tube 10 at the position connecting to the nozzle.

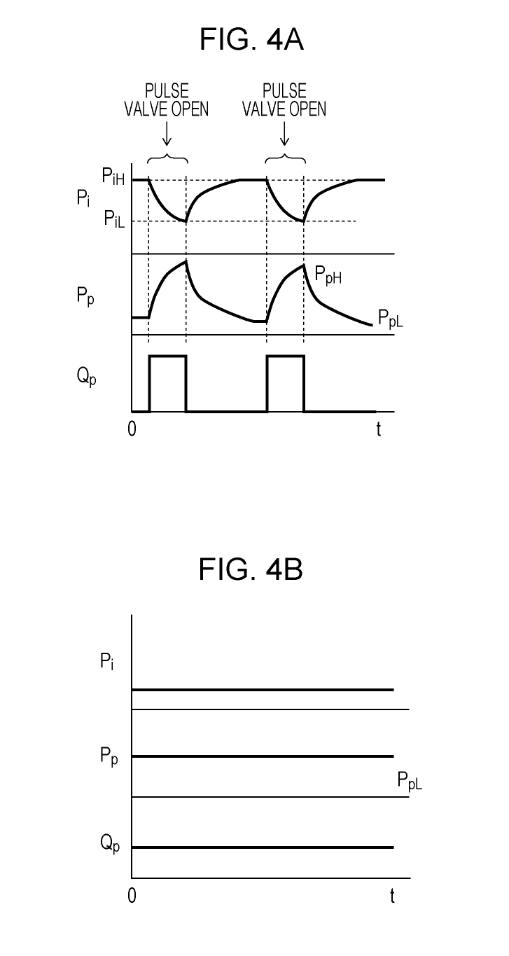

In this embodiment, as shown in FIG. 4A, the amount of gas and liquid droplets 16 injected into the cluster generation part 2 is varied by the pulse valve 34. In FIG. 4A, Qp is the conductance of the pulse valve 34, Pp is the pressure in the cluster generation part 2, and Pi is the gas pressure applied to the nozzle 11.

For comparison, FIG. 4B shows the relationships between Qp, Pp, and Pi in a process in which gas and liquid droplets are continuously injected into the cluster generation part 2 without using a pulse valve, for example, as in the liquid droplet injecting apparatus shown in FIG. 2A (hereinafter, referred to as the continuous injection process).

Comparison of both shows that in this embodiment, a large amount of gas and liquid droplets can be injected at the moment when the pulse valve 34 is open, compared with the continuous injection process. The reason for this is that, in the period of time when the pulse valve 34 is closed, since gas and liquid droplets are not injected, Pp decreases lower than that of the continuous injection process, and the increase of Pp when the pulse valve 34 is open can be reduced.

The partial pressure of the gaseous source material in the connecting tube 10 in this embodiment can be set higher than that of the continuous injection process for the reason described above, and therefore, evaporation of the liquid droplets 16 can be further suppressed. Moreover, because of the suppression of evaporation, the temperature of the nozzle 11 can be increased, and thus, it is possible to effectively suppress deposition of the solid source material.

### Fourth Embodiment

A liquid droplet injecting apparatus according to a fourth embodiment is shown in FIG. 2E.

This apparatus is the same as the liquid droplet injecting apparatus according to the first or second embodiment except that an external heating unit 35 which heats the nozzle 11 is provided. Furthermore, a cluster ion irradiation apparatus including this liquid droplet injection apparatus is the same as that of the previous embodiment.

In the external heating unit 35, by irradiating and heating the nozzle 11 with an electromagnetic wave 36, deposition of the solid source material is suppressed. The electromagnetic wave may be any one of a microwave, infrared light, visible light, and ultraviolet light, or laser light thereof.

Instead of the external heating unit 35 provided in the cluster generation part 2, an external heating unit 37 provided outside the vacuum vessel may be used. In this case, the nozzle may be irradiated with the electromagnetic wave 36 through a window 38 provided on the cluster generation part 2.

In this embodiment, since the electromagnetic wave is directly radiated on the nozzle 11 at the spot on which the solid source material is likely to be deposited, deposition of the solid source material can be efficiently suppressed. Furthermore, since it is possible to avoid heating on the portion of the nozzle 11 on which the solid source material is not deposited, influx of heat into the nozzle 11 and the connecting tube 10 can be reduced compared with the case where a heater 30 is used. Consequently, it is possible to reduce an increase in temperature of the liquid droplets through the connecting tube 10, and therefore, evaporation of the liquid droplets can be reduced, which is the feature of this embodiment.

### Fifth Embodiment

A liquid droplet injecting apparatus according to a fifth embodiment is shown in FIG. 2F.

This apparatus is the same as the liquid droplet injecting apparatus according to the first or second embodiment except that a connecting tube heater 39 is provided on the connecting tube 10. Furthermore, a cluster ion irradiation apparatus including this liquid droplet injection apparatus is the same as that of the previous embodiment.

In this embodiment, the connecting tube 10 can be heated by the connecting tube heater 39, and thus an effect is obtained in which deposition of the solid source material on the inner wall of the connecting tube 10 can be suppressed. The connecting tube heater 39 may heat a part of or most part of the connecting tube 10.

### Sixth Embodiment

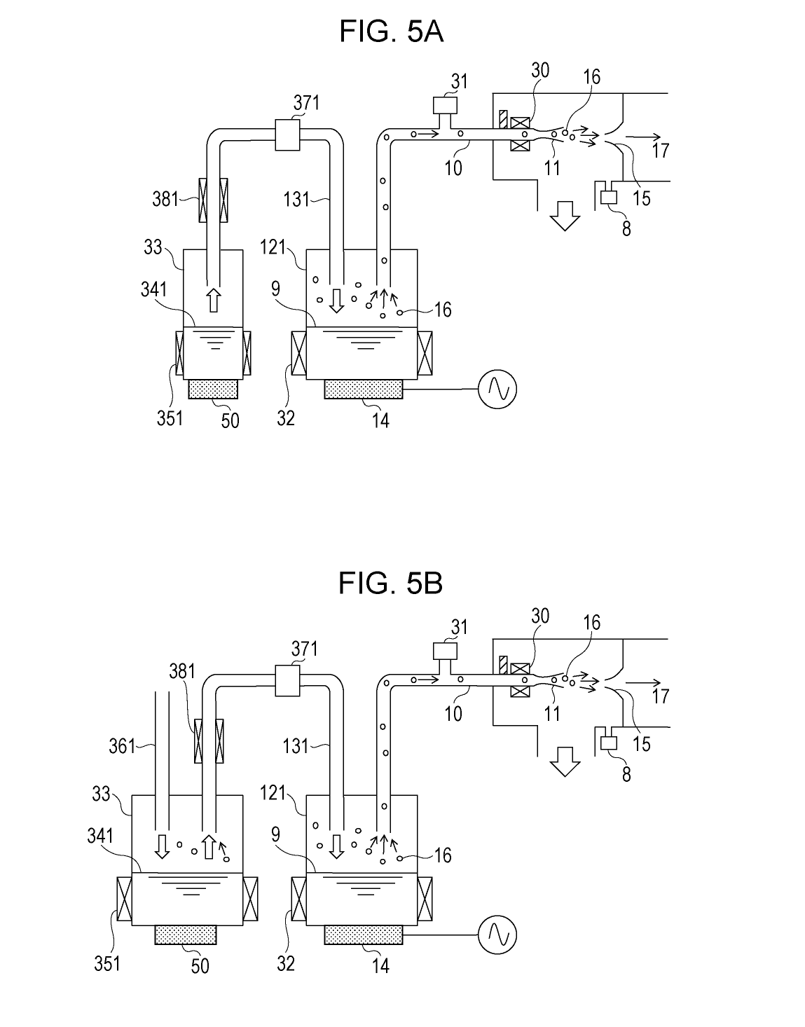

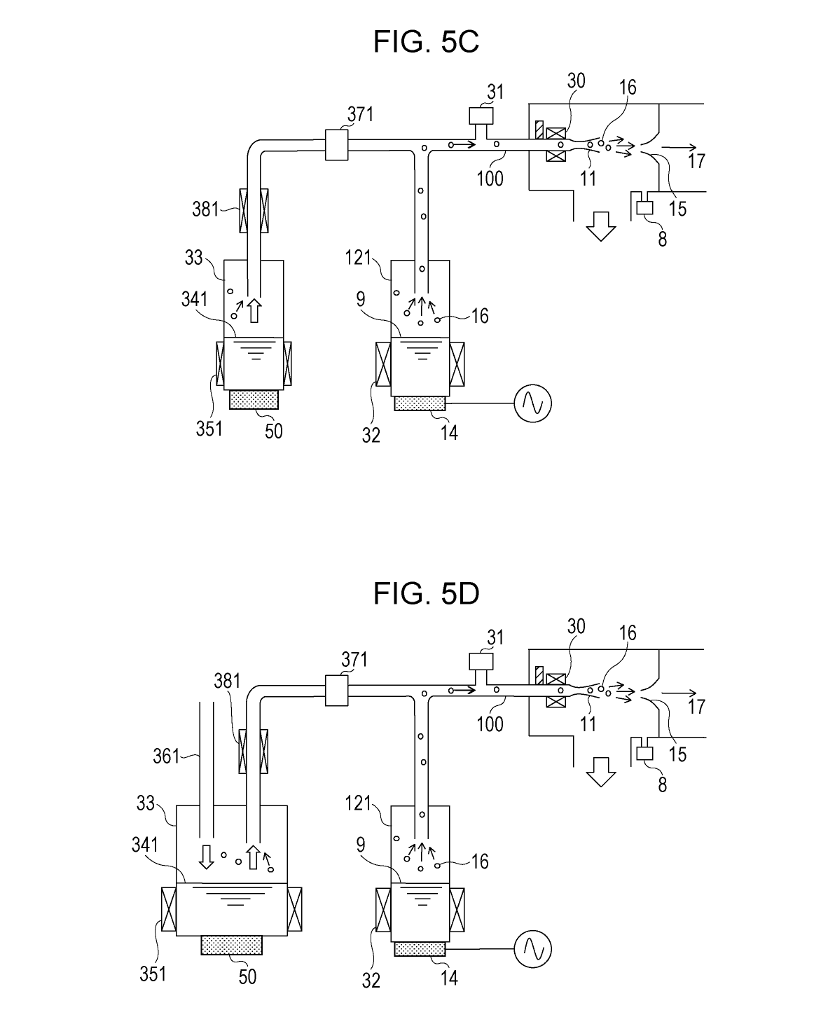

A liquid droplet injecting apparatus according to a sixth embodiment is shown in FIG. 5A.

This apparatus is the same as the liquid droplet injecting apparatus according to the previous embodiment except that a first liquid container 121, a second liquid container 33, and a liquid container connecting tube 131 are provided. Furthermore, a cluster ion irradiation apparatus including this liquid droplet injection apparatus is the same as that of the previous embodiment.

The first liquid container 121 is connected to a nozzle 11 by a connecting tube 10 as in the previous embodiment. Liquid droplets may be generated from a liquid source material 9 using one of or both of a liquid container heater 32 and a vibrator 14 as in the previous embodiment. Furthermore, a connecting tube heater 39 may be provided on the connecting tube 10.

The first liquid container 121 and the second liquid container 33 are connected by the liquid container connecting tube 131. A liquid container connecting tube heater 381 is provided on the liquid container connecting tube 131.

A second liquid 341 is stored in the second liquid container 33, and the second liquid 341 can be heated by a second liquid container heater 351. At least some of the heated second liquid is evaporated and introduced into the first liquid container 121 through the liquid container connecting tube 131. Note that the relationship between the pressure of the vapor and the temperature of the nozzle 11 may be the same as the relationship between the pressure of the source material gas in the connecting tube 10 and the temperature of the nozzle 11 in the first embodiment. Furthermore, vibration may be applied by a second vibrator 50 to the second liquid 341. However, the second vibrator 50 may not be provided.

A liquid container connecting tube valve 371 may be provided on the liquid container connecting tube 131, and the amount of gas introduced from the second liquid container 33 into the first liquid container 121 may be adjusted. Note that the liquid container connecting tube valve 371 may have a function of measuring the internal pressure of the liquid container connecting tube 131. Furthermore, instead of the liquid container connecting tube valve 371, a total pressure gauge or a partial pressure gauge may be provided.

The second liquid 341 may be the same as or different from the liquid source material 9. In the former case, the same source material gas as the liquid source material can be heated by the liquid container connecting tube heater 381 and supplied into the first liquid container 121 at a temperature different from that of the source material gas generated from the liquid source material in the first liquid container 121. The types of liquid source material and source material gas may be the same as those in the first embodiment.

In the latter case, the liquid droplets generated in the first liquid container 121 can be brought into contact with the vapor of the second liquid 341 which is different from the liquid source material constituting the liquid droplets, and therefore, the vapor may be incorporated into the liquid droplets. As a result, an effect is obtained in which liquid droplets containing the liquid source material 9 and the second liquid 341 can be produced.

Furthermore, even in the case where the same liquid is stored in the first liquid container 121 and the second liquid container 33, a substance different from the substance added into the one container may be added into the other container. Furthermore, the concentration of the substance to be added into the one container may be the same as or different from the concentration of the substance to be added into the other container. Although this apparatus includes two liquid containers, another liquid container and a tube for connecting them may be added thereto. Moreover, a gas introduction tube may be added to the first liquid container 121.

### Seventh Embodiment

A liquid droplet injecting apparatus according to a seventh embodiment is shown in FIG. 5B.

This apparatus is the same as the liquid droplet injecting apparatus according to the sixth embodiment except that the second liquid container 33 has a second gas introduction tube 361. Furthermore, a cluster ion irradiation apparatus including this liquid droplet injection apparatus is the same as that of the previous embodiment.

In this embodiment, a gas that is the same as or different from the source material gas may be introduced through the second gas introduction tube 361 as in the previous embodiment. By introducing a gas from the second gas introduction tube 361, an effect is obtained in which liquid droplets can be efficiently generated from the second liquid 341. The liquid droplets move along the gas flow into the first liquid container 121 through the liquid container connecting tube 131, and are guided to the nozzle 11 through the connecting tube 10. The same applies to the vapor generated from the second liquid 341.

Furthermore, the liquid droplets generated in the first liquid container 121 can be brought into contact with the vapor of the second liquid 341 as in the sixth embodiment.

### Eighth Embodiment

A liquid droplet injecting apparatus according to an eighth embodiment is shown in FIG. 5C.

This apparatus is the same as the liquid droplet injecting apparatus according to the sixth embodiment except that the first liquid container 121, the second liquid container 33, and the nozzle 11 are connected by a tube having parallel tube portions 100. Furthermore, a cluster ion irradiation apparatus including this liquid droplet injection apparatus is the same as that of the previous embodiment.

In this embodiment, the liquid droplets and vapor generated in the second liquid container 33, together with the liquid droplets and vapor generated in the first liquid container 121, are guided to the nozzle 11 through the tube having parallel tube portions 100. At that time, the droplets and vapor generated from the second liquid 341 are brought into contact with the liquid source material 9 stored in the first liquid container 121 less likely than the previous embodiment, and an effect is obtained in which mixture of the second liquid 341 in the liquid source material 9 can be suppressed.

Furthermore, as shown in FIG. 5D, a second gas introduction tube 361 may be added to the second liquid container 33 as in the seventh embodiment. Furthermore, a connecting tube heater 39 may be provided on the connecting tube 10.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-096003, filed Apr. 30, 2013, which is hereby incorporated by reference herein in its entirety.

1. A liquid droplet injecting apparatus comprising:
a liquid container which holds a liquid and whose inside pressure can be adjusted;
a liquid droplet generating unit configured to generate liquid droplets from the liquid held in the liquid container;
a nozzle which injects the liquid droplets generated in the liquid container;
a connecting tube which connects the nozzle and the liquid container; and
a first heating unit configured to heat at least one of the connecting tube and the nozzle.

2. The liquid droplet injecting apparatus according to claim 1, wherein the partial pressure of a substance constituting the liquid droplets in the connecting tube is higher than the vapor pressure of the substance.

3. The liquid droplet injecting apparatus according to claim 1, further comprising a gas introduction tube which has an opening disposed in the liquid container and which introduces a gas into the liquid container.

4. The liquid droplet injecting apparatus according to claim 1, wherein the liquid droplet generating unit includes a vibrator which is disposed on the liquid container and which applies vibration to the liquid.

5. The liquid droplet injecting apparatus according to claim 3, wherein, in the liquid droplet generating unit, the opening of the gas introduction tube is disposed below the surface of the liquid in the liquid container.

6. The liquid droplet injecting apparatus according to claim 1, wherein the liquid droplet generating unit includes a second heating unit provided on the liquid container.

7. The liquid droplet injecting apparatus according to claim 1, wherein a valve which changes the flow rate of liquid droplets to be injected is provided on the nozzle, the introduction tube, or therebetween.

8. The liquid droplet injecting apparatus according to claim 1, wherein the first heating unit is a heater provided on at least one of the connecting tube and the nozzle.

9. The liquid droplet injecting apparatus according to claim 1, wherein the first heating unit is a unit configured to heat at least one of the connecting tube and the nozzle by irradiation with an electromagnetic wave.

10. The liquid droplet injecting apparatus according to claim 1, wherein at least one of the nozzle, the connecting tube, and the liquid droplet generating unit is provided with a pressure measuring unit configured to measure a gas pressure.

11. The liquid droplet injecting apparatus according to claim 10, further comprising:
a thermometer provided on the liquid container;
a temperature controller which is connected to the pressure measuring unit and which is configured to control the second heating unit; and
a memory unit configured to send a pressure reference value of a gaseous source material to the temperature controller,
wherein the temperature controller (1) receives the pressure reference value from the memory unit, (2) compares a pressure measurement value measured by the pressure measuring unit with the pressure reference value, and (3) controls the second heating unit such that the difference between the pressure reference value and the pressure measurement value is smaller than a given pressure difference or the latter value is higher than the former value.

12. The liquid droplet injecting apparatus according to claim 1, further comprising:
a second liquid container connected to the liquid container; and
a liquid container connecting tube which connects the liquid container and the second liquid container.

13. The liquid droplet injecting apparatus according to claim 12, further comprising a tube which is connected to the second liquid container and which introduces a gas from the outside of the container into the container.

14. The liquid droplet injecting apparatus according to claim 12, further comprising a tube having parallel tube portions which connects the liquid container and the second liquid container and supplies liquid droplets to the nozzle.

15. An ion source comprising:
the liquid droplet injecting apparatus according to claim 1;
a cluster generation part which houses the nozzle; and
an ionization part which ionizes liquid droplets injected from the nozzle.

16. The ion source according to claim 15, further comprising a partition wall which separates the cluster generation part and the ionization part, wherein the partition wall has an opening through which the liquid droplets pass.

17. A cluster ion irradiation apparatus comprising:
the ion source according to claim 15; and
a stage which holds an object to be irradiated with ions.

18. A surface analyzing device comprising:
the ion source according to claim 15;
a stage which holds an object to be irradiated with ions; and
a detector which detects neutral particles or charged particles released from the object to be irradiated.

19. The surface analyzing device according to claim 18, wherein the detector is a mass spectrometer.
